(19) United States
(12) Patent Application Publication
(10) Pub. No.: US 2024/0080011 A1
(43) Pub. Date: Mar. 7, 2024

(54) BAW RESONATOR AND BAW RESONATOR MANUFACTURING METHOD

(71) Applicant: SAMSUNG ELECTRO-MECHANICS CO., LTD., Suwon-si (KR)

(72) Inventors: Moon Chul LEE, Suwon-si (KR); Jae Hyoung GIL, Suwon-si (KR); Kwang Su KIM, Suwon-si (KR); Sung Jun LEE, Suwon-si (KR); Yong Suk KIM, Suwon-si (KR); Dong Hyun PARK, Suwon-si (KR); Tae Kyung LEE, Suwon-si (KR)

(73) Assignee: SAMSUNG ELECTRO-MECHANICS CO., LTD., Suwon-si (KR)

(21) Appl. No.: 18/112,609

(22) Filed: Feb. 22, 2023

(30) Foreign Application Priority Data
Sep. 6, 2022 (KR) 10-2022-0112716

(51) Int. Cl. H03H 9/17; H03H 3/02

(52) U.S. Cl. CPC H03H 9/172; H03H 3/02

(57) ABSTRACT

A bulk-acoustic wave (BAW) resonator includes a central portion in which a first electrode, a piezoelectric layer, and a second electrode are sequentially stacked on a substrate, and an extension portion extending externally from the central portion, and an insertion layer and a loss prevention film are disposed in the extension portion between the substrate and the second electrode. The loss prevention film is formed to have a thickness of 50 Å to 500 Å. The insertion layer is stacked on the loss prevention film, and has a side surface opposing the central portion, the side surface is formed as a first inclined surface having a first inclination angle. The loss prevention film has a side surface opposing the central portion, the side surface is formed as a second inclined surface having a second inclination angle. The second inclination angle is formed to be greater than the first inclination angle.

### CROSS-REFERENCE TO RELATED APPLICATIONS

This application claims the benefit under 35 USC § 119(a) of Korean Patent Application No. 10-2022-0112716, filed on Sep. 6, 2022, in the Korean Intellectual Property Office, the entire disclosure of which is incorporated herein by reference for all purposes.

### BACKGROUND

### 1. Field

The following description relates to a bulk-acoustic wave (BAW) resonator, and BAW resonator manufacturing method.

### 2. Description of Related Art

In view of the miniaturization of wireless communication devices, the miniaturization of high-frequency components has been actively undertaken. For example, a filter in the form of a bulk-acoustic wave (BAW) resonator using a technology that manufactures a semiconductor thin film wafer may be implemented.

A BAW resonator is a thin film-type device, implemented as a filter, inducing resonance using piezoelectric properties of a piezoelectric dielectric material deposited on a silicon wafer, a semiconductor substrate.

Interest in a 5G communications technology has increased, and a technology implementable in a candidate band has been actively developed. For example, a BAW resonator that smoothly operates as a filter in various bands, such as a 2 GHz to 3 GHz frequency band in addition to a 4 GHz to 6 GHz frequency band, has been desired. Accordingly, improvements in the filter properties of the BAW resonator are desirable.

### SUMMARY

This Summary is provided to introduce a selection of concepts in a simplified form that is further described below in the Detailed Description. This Summary is not intended to identify key features or essential features of the claimed subject matter, nor is it intended to be used as an aid in determining the scope of the claimed subject matter.

In a general aspect, a bulk-acoustic wave (BAW) resonator includes a central portion in which a first electrode, a piezoelectric layer, and a second electrode are sequentially stacked on a substrate; and an extension portion that extends externally from the central portion, and an insertion layer and a loss prevention film are disposed in the extension portion between the substrate and the second electrode, wherein the loss prevention film is formed to have a thickness of 50 Å to 500 Å, wherein the insertion layer is stacked on the loss prevention film, and has a side surface that opposes the central portion, and the side surface is formed as a first inclined surface having a first inclination angle, wherein the loss prevention film has a side surface that opposes the central portion, and the side surface of the loss prevention film is formed as a second inclined surface having a second inclination angle, and wherein the second inclination angle is greater than the first inclination angle.

The second inclined surface may extend from the first inclined surface.

The insertion layer and the loss prevention film may be disposed between the first electrode and the piezoelectric layer in the extension portion.

The loss prevention film may include aluminum nitride (AlN).

The insertion layer and the loss prevention film may be disposed between the piezoelectric layer and the second electrode in the extension portion.

The loss prevention film may be formed of a metal material.

The insertion layer and the loss prevention film may be disposed between the substrate and the first electrode in the extension portion.

The BAW resonator may further include a seed layer disposed on a lower portion of the first electrode, wherein at least a portion of the seed layer is disposed between the insertion layer and the first electrode.

The second inclination angle of the loss prevention film may be equal to or greater than 50°.

The loss prevention film may be formed of a material that is the same as a material of the piezoelectric layer.

An upper end of the second inclined surface may be spaced apart from a lower end of the first inclined surface by a predetermined distance to be in contact with a lower surface of the insertion layer.

In a general aspect, method of manufacturing a bulk-acoustic wave (BAW) resonator including a central portion in which a plurality of thin film layers are stacked and an extension portion that extends externally from the central portion and having an insertion layer additionally disposed thereon includes forming a first thin film layer; forming a loss prevention film on the first thin film layer; forming the insertion layer on an entire area of the loss prevention film; removing the insertion layer disposed in the central portion after forming the insertion layer on the entire area of the loss prevention film; exposing the first thin film layer by removing the loss prevention film that is exposed externally of the insertion layer; and forming a second thin film layer on the exposed first thin film layer, wherein the loss prevention film is formed to have a thickness of 50 Å to 500 Å, wherein the removing of the insertion layer comprises forming a side surface of the insertion layer that opposes the central portion as a first inclined surface, wherein the removing of the loss prevention film comprises forming a side surface of the loss prevention film that opposes the central portion as a second inclined surface, and wherein the second inclined surface extends from the first inclined surface.

The removing of the insertion layer may be performed by a dry etching method, and the removing of the loss prevention film may be performed by a wet etching method.

In the forming of the loss prevention film, the second inclined surface may have an inclination angle equal to or greater than 50°.

The first thin film layer may be a lower electrode, and the second thin film layer may be a piezoelectric layer.

The first thin film layer may be a piezoelectric layer, and the second thin film layer may be an upper electrode.

Other features and aspects will be apparent from the following detailed description, the drawings, and the claims.

### BRIEF DESCRIPTION OF DRAWINGS

FIG. 1 illustrates a plan view of an example bulk-acoustic wave (BAVV) resonator, in accordance with one or more embodiments.

FIG. 2 illustrates a cross-sectional view of FIG. 1 taken along line I-I′.

FIG. 3 illustrates an enlarged view of portion A of FIG. 2.

FIGS. 4 to 8 are diagrams illustrating a method of manufacturing an example BAW resonator illustrated in FIG. 2.

FIG. 9 illustrates a cross-sectional view of an example BAW resonator, in accordance with one or more embodiments.

FIG. 10 illustrates a cross-sectional view of an example BAW resonator, in accordance with one or more embodiments.

FIG. 11 illustrates a partial cross-sectional view of an example BAW resonator, in accordance with one or more embodiments.

Throughout the drawings and the detailed description, unless otherwise described or provided, the same drawing reference numerals may be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Throughout the specification, when a component or element is described as being “on”, “connected to,” “coupled to,” or “joined to” another component, element, or layer it may be directly (e.g., in contact with the other component or element) “on”, “connected to,” “coupled to,” or “joined to” the other component, element, or layer or there may reasonably be one or more other components, elements, layers intervening therebetween. When a component or element is described as being “directly on”, “directly connected to,” “directly coupled to,” or “directly joined” to another component or element, there can be no other elements intervening therebetween. Likewise, expressions, for example, “between” and “immediately between” and “adjacent to” and “immediately adjacent to” may also be construed as described in the foregoing.

As used herein, the term “and/or” includes any one and any combination of any two or more of the associated listed items. The phrases “at least one of A, B, and C”, “at least one of A, B, or C”, and the like are intended to have disjunctive meanings, and these phrases “at least one of A, B, and C”, “at least one of A, B, or C”, and the like also include examples where there may be one or more of each of A, B, and/or C (e.g., any combination of one or more of each of A, B, and C), unless the corresponding description and embodiment necessitates such listings (e.g., “at least one of A, B, and C”) to be interpreted to have a conjunctive meaning.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

The terminology used herein is for describing various examples only and is not to be used to limit the disclosure. The articles “a,” “an,” and “the” are intended to include the plural forms as well, unless the context clearly indicates otherwise. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment, e.g., as to what an example or embodiment may include or implement, means that at least one example or embodiment exists where such a feature is included or implemented, while all examples are not limited thereto.

Spatially relative terms such as “above,” “upper,” “below,” and “lower” may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

One or more examples provide a bulk-acoustic wave (BAW) resonator which has improved performance.

One or more examples also provide a method of manufacturing a BAW resonator that prevents a lower electrode from being lost during a manufacturing process.

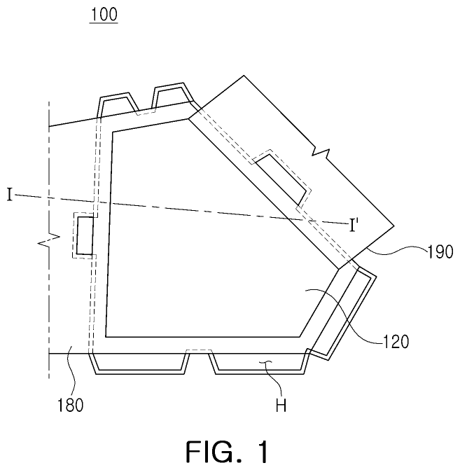

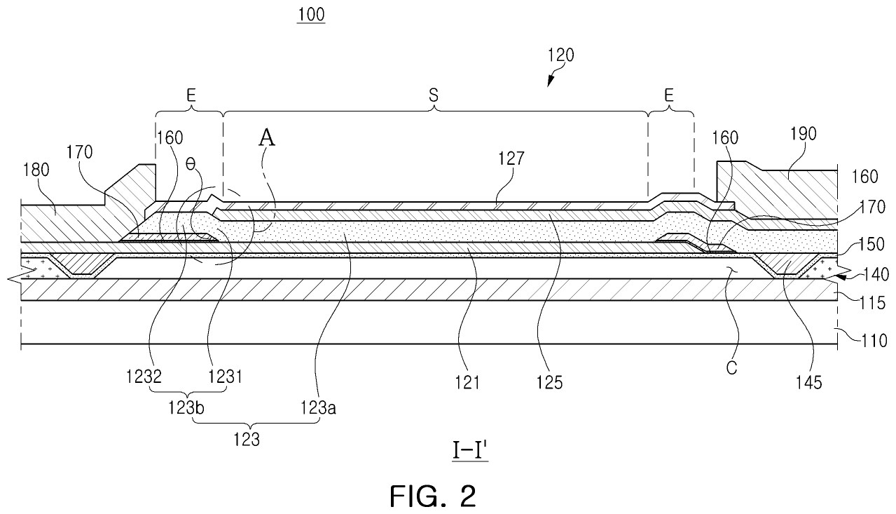

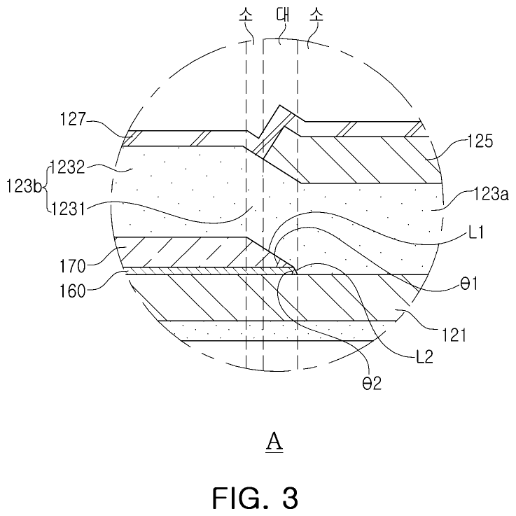

FIG. 1 illustrates a plan view of an example acoustic wave resonator, in accordance with one or more embodiments, FIG. 2 is a cross-sectional view of FIG. 1 taken along line I-I′, and FIG. 3 is an enlarged view of portion A of FIG. 2.

Referring to FIGS. 1 to 3, the example acoustic wave resonator 100, in accordance with one or more embodiments, may be a bulk-acoustic wave (BAW) resonator, and may be formed by stacking a plurality of thin film layers on a substrate 110.

In an example, the substrate 110 may be a silicon substrate. In non-limited examples, a silicon wafer or a silicon on insulator (SOI) type substrate may be used as the substrate 110.

An insulating layer 115 may be formed on an upper surface of the substrate 110 to electrically isolate the substrate 110 and a resonant portion 120 from each other. Additionally, the insulating layer 115 may also prevent the substrate 110 from being etched by an etching gas when a cavity C is formed in the process of manufacturing an acoustic wave resonator.

In non-limiting examples, the insulating layer 115 may be formed of at least one of silicon dioxide (SiO₂), silicon nitride (Si₃N₄), aluminum oxide (Al₂O₃), and aluminum nitride (AlN), and may be formed through one process among chemical vapor deposition, RF magnetron, and evaporation, as only examples.

A plurality of thin film layers may be stacked on the insulating layer 115. The plurality of thin film layers may include a support layer 140, a membrane layer 150, and a first electrode 121, a piezoelectric layer 123, and a second electrode 125 which form the resonant portion 120.

The support layer 140 may be formed on the insulating layer 115, and may be disposed around the cavity C and an etch-stop portion 145 to surround the cavity C and the etch-stop portion 145.

The cavity C may be formed as an empty space, and may be formed by removing a portion of a sacrificial layer formed in the process of forming the support layer 140. Accordingly, the support layer 140 may be formed of an easily etchable material such as polysilicon or a polymer, but the examples are not limited thereto.

The etch-stop portion 145 may be disposed along a boundary of the cavity C. The etch-stop portion 145 may be provided to prevent etching from progressing beyond a cavity region in the process of forming the cavity C.

The membrane layer 150 may be formed on the support layer 140, and may form an upper surface of the cavity C. Accordingly, the membrane layer 150 may be also formed of a material that is not easily removed in the process of forming the cavity C.

For example, when a halide-based etching gas such as fluorine (F) or chlorine (Cl) is used to remove a portion (for example, a cavity region) of the support layer 140, the membrane layer 150 may be formed of the above-described etching gas and a material having low reactivity. In this example, the membrane layer 150 may include at least one of silicon dioxide (SiO₂) and silicon nitride (Si₃N₄).

Additionally, the membrane layer 150 may be formed of a dielectric layer containing at least one of magnesium oxide (MgO), zirconium oxide (ZrO₂), aluminum nitride (AlN), lead zirconate titanate (PZT), gallium arsenic (GaAs), hafnium oxide (HfO₂, aluminum oxide (Al₂O₃), titanium oxide (TiO₂) and zinc oxide (ZnO), or may be formed of a metal layer containing at least one of aluminum (Al), nickel (Ni), chromium (Cr), platinum (Pt), gallium (Ga), and hafnium (Hf). However, the examples are not limited thereto.

A seed layer (not illustrated) formed of aluminum nitride (AlN) may be formed on the membrane layer 150 to deposit the first electrode 121. Specifically, the seed layer may be disposed between the membrane layer 150 and the first electrode 121. The seed layer may be formed using a dielectric or metal having an HCP structure in addition to AlN. When the metal is used, the seed layer may be formed of titanium (Ti), for example.

The resonant portion 120 may include the first electrode 121, the piezoelectric layer 123, and the second electrode 125. In the resonant portion 120, the first electrode 121, the piezoelectric layer 123, and the second electrode 125 may be sequentially stacked in a direction from the bottom. Accordingly, in the resonant portion 120, the piezoelectric layer 123 may be disposed between the first electrode 121 and the second electrode 125.

Since the resonant portion 120 is formed on the membrane layer 150, the membrane layer 150, the first electrode 121, the piezoelectric layer 123, and the second electrode 125 may be sequentially stacked on an upper portion of the substrate 110 to form the resonant portion 120.

The resonant portion 120 may resonate the piezoelectric layer 123 depending on signals applied to the first electrode 121 and the second electrode 125 to generate a resonance frequency or an anti-resonance frequency.

As illustrated in FIG. 2, the resonant portion 120 may be divided into a central portion S and an extension portion E according to a stack structure.

The central portion S, which is a region in which the first electrode 121, the piezoelectric layer 123, and the second electrode 125 are substantially flatly stacked, may be a region that is disposed at the center of the resonant portion 120, and may be a resonance active region in which resonance is substantially generated. For example, the central portion S may be a region of the resonant portion 120 in which an insertion layer 170 (to be described below) is not disposed.

The extension portion E, which is a region extending from the central portion S externally of the central portion S, may be a region including the insertion layer 170. More specifically, the extension portion E may be a region that includes the insertion layer 170 and the piezoelectric layer 123, and may further include at least one of the first electrode 121 and the second electrode 125.

On the basis of a boundary between the central portion S and the extension portion E, the extension portion E may be formed to have a continuous ring shape along the above-described boundary from the outside of the central portion S. However, as necessary, the extension portion E may be formed to have a discontinuous ring shape in which some regions are disconnected.

Accordingly, as illustrated in FIG. 2, in a cross-section of the resonant portion 120 taken to cross the central portion S, the extension portion E may be disposed at each of opposite ends of the central portion S. Additionally, the insertion layer 170 may be disposed on both sides of the extension portion E, which is disposed at the opposite ends of the central portion S.

In the extension portion E, the piezoelectric layer 123 and the second electrode 125 may be disposed on the insertion layer 170.

Referring to FIG. 3, the insertion layer 170 may have a first inclined surface L1 having a thickness that increases as a distance from the central portion S increases. Additionally, in the present example embodiment, an upper surface of the piezoelectric layer 123 may be flatly formed. Accordingly, the piezoelectric layer 123 positioned in the extension portion E may be formed to have a shape having a thickness decreasing along an inclined surface of the insertion layer 170 toward the outside.

In the present example embodiment, the extension portion E may be viewed as being included in the resonant portion 120, and accordingly, resonance may occur in the extension portion E as well. However, the examples are not limited thereto, and resonance may not occur in the extension portion E and resonance may occur only in the central portion S, depending on a structure of the extension portion E.

The first electrode 121 and the second electrode 125 may be formed of a conductor, and for example, may be formed of a metal including gold, molybdenum, ruthenium, iridium, aluminum, platinum, titanium, tungsten, palladium, tantalum, chromium, nickel, or at least one of gold, molybdenum, ruthenium, iridium, aluminum, platinum, titanium, tungsten, palladium, tantalum, chromium, and nickel, but the present disclosure is not limited thereto.

In the resonant portion 120, the first electrode 121 may be formed to have an area larger than an area of the second electrode 125, and a first metal layer 180 may be formed on the first electrode 121 along an outer periphery of the first electrode 121. Accordingly, the first metal layer 180 may be spaced apart from the second electrode 125 by a predetermined distance, and may be disposed to surround the resonant portion 120.

In the central portion S, the first electrode 121 may be disposed on the membrane layer 150, and may be formed to be generally flat. Additionally, since the second electrode 125 is disposed on the piezoelectric layer 123, the second electrode 125 may be formed to be generally flat depending on a shape of the piezoelectric layer 123. Accordingly, in the resonant portion 120, a distance between the first electrode 121 and the second electrode 125 may be formed to be generally flat.

The first electrode 121, which is a lower electrode, may be implemented as one of an input electrode and an output electrode to input and output an electrical signal such as a radio frequency (RF) signal.

The second electrode 125, which is an upper electrode, may be entirely disposed within the central portion S, and may be partially disposed within the extension portion E. More specifically, in the present example embodiment, the second electrode 125 may be disposed to cover the entire piezoelectric layer 123 positioned in the central portion S of the piezoelectric layer 123. In the extension portion E, the second electrode 125 may be disposed such that a side surface of the second electrode 125 forming an end is positioned on the first inclined surface L1 of the insertion layer 170. For example, the side surface of the second electrode 125 may be disposed along the first inclined surface L1 of the insertion layer 170.

In the present example embodiment, the side surface of the second electrode 125 may refer to a portion illustrated as a side surface in the cross-sectional view illustrated in FIG. 2. Accordingly, in a cross-section of the resonant portion 120 taken to cross the central portion S, an end, a side surface, of the second electrode 125 may be disposed within the extension portion E. Additionally, at least a portion of the end of the second electrode 125 disposed within the extension portion E may be disposed to overlap the insertion layer 170. More specifically, the end of the second electrode 125 may be disposed to overlap the first inclined surface L1 of the insertion layer 170.

Here, overlapping may mean that when the second electrode 125 is projected on a plane on which the insertion layer 170 is disposed, a shape of the second electrode 125 projected on the plane overlaps the first inclined surface L1 of the insertion layer 170.

As illustrated in FIG. 2, at least a portion of the second electrode 125 may be connected to a second metal layer 190 through the extension portion E. Accordingly, in a portion of the second electrode 125 connected to the second metal layer 190, the end of the second electrode 125 may not be disposed within the extension portion E.

Accordingly, in the present example embodiment, the end of the second electrode 125 may refer to a side surface of a remaining portion of the second electrode 125 excluding a portion connected to the second metal layer 190 through the extension portion E.

The second electrode 125 may be implemented as any one of an input electrode and an output electrode to input and output an electrical signal such as a radio frequency (RF) signal. That is, the second electrode 125 may be implemented as the output electrode when the first electrode 121 is implemented as the input electrode, and the second electrode 125 may be implemented as the input electrode when the first electrode 121 is implemented as the output electrode.

When the end of the second electrode 125 is positioned within the extension portion E, a local structure of acoustic impedance of the resonant portion may be formed to have a small/large/small structure from the central portion S. Reflectivity to reflect a lateral wave into the resonant portion 120 may be increased. Accordingly, most of the lateral waves may not escape externally of the resonant portion 120, and may be reflected into the resonant portion 120, such that a BAW resonator may have improved performance.

In an example, the lateral wave may include a wave that forms spurious resonance while travelling in a surface direction of the resonant portion 120.

The piezoelectric layer 123, a portion causing a piezoelectric effect in which electrical energy is converted into mechanical energy in the form of elastic waves, may be formed on the first electrode 121 and the insertion layer 170 to be described below.

As a material of the piezoelectric layer 123, materials such as, but not limited to, zinc oxide (ZnO), aluminum nitride (AlN), doped aluminum nitride, lead zirconate titanate, quartz, or the like may be selectively used. When the doped aluminum nitride is used, a rare earth metal, a transition metal, or an alkaline earth metal may be further included. The rare earth metal may include at least one of scandium (Sc), erbium (Er), yttrium (Y), and lanthanum (La). The transition metal may include at least one of hafnium (Hf), titanium (Ti), zirconium (Zr), tantalum (Ta), and niobium (Nb), but is not limited thereto. Additionally, the alkaline earth metal may include magnesium (Mg).

In the present example embodiment, the piezoelectric layer 123 may be implemented by doping aluminum nitride (AlN) with scandium (Sc). In this example, a piezoelectric constant may be increased, such that Kₜ² of an acoustic wave resonator may be increased.

The piezoelectric layer 123 according to the present example embodiment may include a piezoelectric portion 123a disposed in the central portion S and a bent portion 123b disposed in the extension portion E.

The piezoelectric portion 123a may be a portion directly stacked on an upper surface of the first electrode 121. Accordingly, the piezoelectric portion 123a may be interposed between the first electrode 121 and the second electrode 125, and accordingly may be formed to be formed together with the first electrode 121 and the second electrode 125.

The bent portion 123b may be defined as a region extending externally from the piezoelectric portion 123a to be positioned within the extension portion E.

The bent portion 123b may be disposed on the insertion layer 170 to be described below, and may be formed in a form in which an upper surface thereof is raised along a shape of the insertion layer 170. Accordingly, the piezoelectric layer 123 may be formed to be bent at a boundary between the piezoelectric portion 123a and the bent portion 123b, and the bent portion 123b may be raised to correspond to a thickness and shape of the insertion layer 170.

The bent portion 123b may be divided into an inclined portion 1231 and an extended portion 1232.

The inclined portion 1231 may refer to a portion that is formed to be inclined along the first inclined surface L1 of the insertion layer 170 to be described below. Additionally, the extended portion 1232 may refer to a portion that extends externally from the inclined portion 1231.

The inclined portion 1231 may be formed to be parallel to the first inclined surface L1 of the insertion layer 170, and an inclination angle of the inclined portion 1231 may be formed to be equal to a first inclination angle θ1 of the first inclined surface L1.

In the present example embodiment, the insertion layer 170 may be disposed between the first electrode 121 and the second electrode 125, and may be disposed on a loss prevention film 160 to be described below. The insertion layer 170 may be partially disposed within the resonant portion 120, and at least a portion of the insertion layer 170 may be disposed between the first electrode 121 and the piezoelectric layer 123.

In the present example embodiment, the insertion layer 170 may be disposed in a region excluding the central portion S. For example, the insertion layer 170 may be disposed on the substrate 110 in a portion of a region excluding the central portion S, or may be disposed on the entire region.

The insertion layer 170 may be disposed on the outside of the central portion S, and may be disposed between a plurality of thin film layers. In the present example embodiment, the insertion layer 170 may be stacked on the first electrode 121. However, the examples are not limited thereto.

A side surface of the insertion layer 170 opposing the central portion S may be formed as the first inclined surface L1 having the first inclination angle θ1. Thus, the insertion layer 170 may be formed on the first inclined surface L1 to have a thickness that increases as a distance from the central portion S increases.

The insertion layer 170 may also perform an operation of protecting the first electrode 121 when a piezoelectric layer is patterned in a process of manufacturing a BAW resonator, and accordingly may be formed to have a predetermined thickness or more. Additionally, when the insertion layer 170 is excessively thick, a difficulty level of a process performed outside the resonant portion 120 may be increased. Considering such a situation, in the present example embodiment, a thickness of the insertion layer 170 may be formed in a range of 3000 Ê to 5000 Ê, but the one or more examples are not limited thereto.

Additionally, when the first inclination angle 81 of the insertion layer 170 is excessively small (for example, 5° or less), the insertion layer 170 may need to be formed to have an excessively small thickness, or the first inclined surface L1 may need to be formed to have a large area so as to manufacture the insertion layer 170, such that practical implementation may be difficult.

Conversely, when the first inclination angle 81 is excessively large (for example, 70° or more), the crystallinity of the piezoelectric layer 123 deposited on an upper surface of the insertion layer 170 may be lowered, and cracks or the like are likely to occur in a bent portion. Accordingly, in the present example embodiment, the inclination angle 81 of the inclined surface L1 may be formed to be in a range of 5° to 70°.

The insertion layer 170 may be formed of a dielectric such as, but not limited to, silicon oxide (SiO₂), aluminum nitride (AlN), aluminum oxide (Al₂O₃), silicon nitride (Si₃N₄), magnesium oxide (MgO), zirconium oxide (ZrO₂), lead zirconate titanate (PZT), gallium arsenic (GaAs), hafnium oxide (HfO₂), titanium oxide (TiO₂), or zinc oxide (ZnO), but may be formed of a material different from a material of the piezoelectric layer 123.

Additionally, the insertion layer 170 may be implemented with a metal material. When a BAW resonator according to the present example embodiment is implemented for 5G communication, heat generated in the resonant portion 120 may need to be smoothly dissipated due to a lot of heat being generated in the resonant portion 120. Accordingly, the insertion layer 170 according to the present example embodiment may be formed of an aluminum alloy material containing scandium (Sc).

Additionally, the insertion layer 170 may be formed of a SiO₂ thin film in which nitrogen (N) or fluorine (F) is implanted.

Since the insertion layer 170 is provided, the extension portion E may have an increased acoustic impedance mismatch as compared to the central portion S. Accordingly, the extension portion E may operate as a frame reflecting a lateral elastic wave toward the outside of the resonant portion 120 from among lateral elastic waves generated in the central portion S to the central portion S, thereby reducing energy loss of an elastic wave. Accordingly, a high Q-factor may be secured.

The high Q-factor may increase blocking properties of other frequency bands in implementing a filter or duplexer with a BAW resonator.

In the acoustic wave resonator according to the present example embodiment, the loss prevention film 160 may be disposed on a lower portion of the insertion layer 170. The loss prevention film 160 may be disposed between a plurality of thin film layers, and may be disposed between the first electrode 121 and the insertion layer 170 in the present example embodiment. Accordingly, the insertion layer 170 may be substantially disposed on the loss prevention film 160.

In an example, the loss prevention film 160 may be formed on the entire surface of the first electrode 121 to protect the first electrode 121 in the process of patterning the insertion layer 170. When the patterning of the insertion layer 170 is completed, a portion disposed externally of the insertion layer 170 may be removed. Accordingly, in a BAW resonator that has been manufactured, the loss prevention film 160 may be disposed only on a lower portion of the insertion layer 170.

Typically, without the loss prevention film 160, the insertion layer 170 may be directly disposed on the first electrode 121. Accordingly, a portion of the first electrode 121 may be removed together with the insertion layer 170 by an etching gas (for example, O₂ or Cl) used in a process of depositing the insertion layer 170 on the first electrode 121 and patterning the insertion layer 170 among processes of manufacturing a BAW resonator. As a result, the first electrode 121 positioned in the central portion S may have increased surface roughness, which may act as an unfavorable condition for crystal orientation during deposition/growth of the piezoelectric layer 123.

Accordingly, in the present example embodiment, the loss prevention film 160 may be formed of a material having high dry etch selectivity and a material of the insertion layer 170, thereby improving frequency dispersion caused by loss of the first electrode 121.

The loss prevention film 160 according to the present example embodiment may include, as an example, aluminum nitride (AlN). However, the one or more examples are not limited thereto, and may be formed of a dielectric or metal having an HCP structure in addition to aluminum nitride (AlN).

A dielectric material having an HCP structure such as aluminum nitride (AlN) may have high dry etch selectivity with respect to the insertion layer 170, thereby effectively performing an operation of the loss prevention film 160.

However, the one or more examples are not limited thereto, and a material or thickness of the loss prevention film 160 is not limited as long as the loss prevention film 160 protects the first electrode 121 without being removed in a process of etching the insertion layer 170. For example, the loss prevention film 160 may be formed of various materials having high dry etch selectivity with respect to the insertion layer 170, such as silicon oxide (SiO₂), aluminum oxide (Al₂O₃), silicon nitride (Si₃N₄), magnesium oxide (MgO), zirconium oxide (ZrO₂), lead zirconate titanate (PZT), gallium arsenic (GaAs), hafnium oxide (HfO₂), titanium oxide (TiO₂), zinc oxide (ZnO), and the like.

Referring to FIG. 3, a side surface of the loss prevention film 160 opposing the central portion S may be formed as a second inclined surface L2 having a second inclination angle θ2. Thus, the loss prevention film 160 may be formed on the second inclined surface L2 to have a thickness that increases as a distance from the central portion S increases. The second inclined surface L2 of the loss prevention film 160 may be formed in the process of partially removing the loss prevention film 160 through an etching process. In the present example embodiment, the loss prevention film 160 may be removed by a wet etching method. Accordingly, the inclination angle θ2 of the second inclined surface L2 may be greater than the inclination angle θ1 of the first inclined surface L1 of the insertion layer 170 formed by a dry etching method.

In the present example embodiment, the second inclination angle θ2 of the second inclined surface L2 may be formed as an acute angle. However, in some examples, the second inclination angle θ2 of the second inclined surface L2 may be also formed as an obtuse angle.

Additionally, in an example, the loss prevention film 160 according to the present example embodiment may be formed to be thinner than the insertion layer 170.

However, when the loss prevention film 160 is excessively thin, the loss prevention film 160 may not be easily formed to have a uniform thickness. As a result, the loss prevention film 160 may be lost together with the insertion layer 170 in the process of patterning the insertion layer 170, such that the first electrode 121 may be exposed. In this example, the operation of the loss prevention film 160 to prevent the loss of the first electrode 121, may not be properly performed, such that the loss prevention film 160 may be formed to have a thickness of 10 Å or more in the present example embodiment.

Additionally, when the loss prevention film 160 is excessively thick, a BAW resonator may have degraded performance due to the loss prevention film 160. Through experiments, it may be confirmed that when a thickness of the loss prevention film 160 exceeds 500 Å, the BAW resonator has rapidly degraded filter performance (for example, an increase in insertion loss). This may be because a step difference increases at a boundary between the insertion layer 170 and the first electrode 121 due to an increase in the thickness of the loss prevention film 160, and accordingly unnecessary grooves or cracks may occur in a bent portion of the piezoelectric layer 123 (a boundary between a piezoelectric portion and the curved portion).

Accordingly, in the present example embodiment, the loss prevention film 160 may be formed to have a thickness of 10 Å to 500 Å, and may be formed to have a thickness of 100 Å so as to 300 Å to enhance manufacturing reliability.

The cavity C may be formed by supplying an etching gas (or an etching solution) to an inlet hole (H in FIG. 1) to remove a portion of the support layer 140 in the process of manufacturing an acoustic wave resonator.

The protective film 127 may be disposed along a surface of the acoustic wave resonator 100 to protect the acoustic wave resonator 100 from the outside. The protective film 127 may be disposed along a surface formed by the second electrode 125 and the bent portion 123b of the piezoelectric layer 123.

As the protective film 127, a dielectric layer containing one material among silicon nitride (Si₃N₄), silicon oxide (SiO₂), magnesium oxide (MgO), zirconium oxide (ZrO₂), aluminum nitride (AlN), lead zirconate titanate (PZT), gallium arsenic (GaAs), hafnium oxide (HfO₂), aluminum oxide (Al₂O₃), titanium oxide (TiO₂), and zinc oxide (ZnO) may be used, but the one or more examples are not limited thereto.

In an example, the protective film 127 may be formed of a single layer, but may also be formed by stacking two layers formed of different materials, as necessary. Additionally, the protective film 127 may be partially removed for frequency control in a final process. For example, a thickness of the protective film 127 may be adjusted in a subsequent process.

The first electrode 121 and the second electrode 125 may extend externally of the resonant portion 120. Additionally, the first metal layer 180 and the second metal layer 190 may be disposed on upper surfaces of the extended portions, respectively.

The first metal layer 180 and the second metal layer 190 may be formed of a material such as, but not limited to, gold (Au), a gold-tin (Au—Sn) alloy, copper (Cu), a copper-tin (Cu—Sn) alloy, aluminum (Al), and an aluminum alloy. In an example, the aluminum alloy may be an aluminum-germanium (Al—Ge) alloy or an aluminum-scandium (Al—Sc) alloy.

The first metal layer 180 and the second metal layer 190 may be implemented as a connection wire to electrically connect electrodes 121 and 125 of the acoustic wave resonator, according to the present example embodiment, to electrodes of another acoustic wave resonator disposed to be adjacent thereto or a terminal for external connection on the substrate 110. However, the one or more examples are not limited thereto.

The first metal layer 180 may pass through the protective film 127 to be bonded to the first electrode 121. Additionally, in the resonant portion 120, the first electrode 121 may be formed to have an area that is larger than an area of the second electrode 125, and the first metal layer 180 may be formed on a circumferential portion of the first electrode 121. Accordingly, the first metal layer 180 may be disposed along a circumference of the resonant portion 120, and may be disposed to surround the second electrode 125. However, the one or more examples are not limited thereto.

A method of manufacturing the BAW resonator, in accordance with one or more embodiments, will be described.

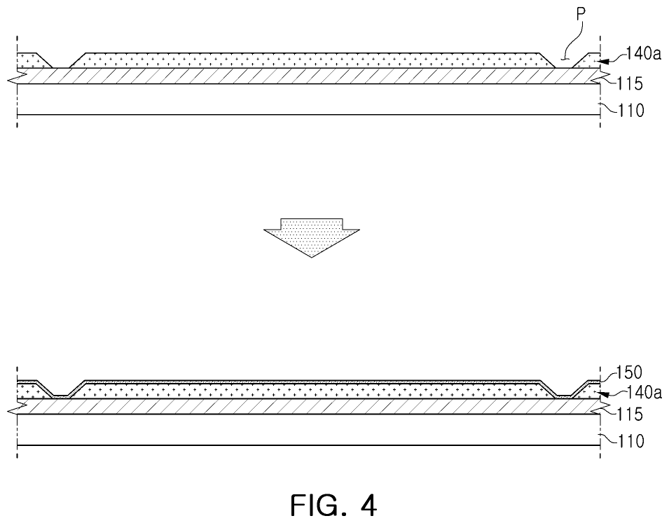

FIGS. 4 to 8 are diagrams illustrating a method of manufacturing the BAW resonator illustrated in FIG. 2.

First, referring to FIG. 4, in the method of manufacturing the BAW resonator, in accordance with one or more embodiments, the insulating layer 115 and a sacrificial layer 140a may be formed on the substrate 110, and the sacrificial layer 140a passing through a pattern P may be formed. Accordingly, the insulating layer 115 may be exposed externally through the pattern P.

The insulating layer 115 may be formed of magnesium oxide (MgO), zirconium oxide (ZrO₂), aluminum nitride (AlN), lead zirconate titanate (PZT), gallium arsenic (GaAs), hafnium oxide (HfO₂), aluminum oxide (Al₂O₃), titanium oxide (TiO₂), zinc oxide (ZnO), silicon nitride (SiN) or silicon oxide (SiO₂). However, the one or more examples are not limited thereto.

The pattern P formed on the sacrificial layer 140a may have a trapezoidal cross-section having an upper surface width wider than a lower surface width.

A portion of the sacrificial layer 140a may be removed through a subsequent etching process to form a cavity (C in FIG. 2), and a remaining portion of the sacrificial layer 140a may form the support layer 140. Accordingly, the sacrificial layer 140a may be formed of an easily etchable material such as polysilicon or a polymer. However, the one or more examples are not limited thereto.

Subsequently, the membrane layer 150 may be formed on the sacrificial layer 140a. The membrane layer 150 may be formed to have a uniform thickness along a surface of the sacrificial layer 140a. The thickness of the membrane layer 150 may be smaller than a thickness of the sacrificial layer 140a.

The membrane layer 150 may be at least one of silicon dioxide (SiO₂) and silicon nitride (Si₃N₄). Additionally, the membrane layer 150 may be formed of a dielectric layer containing at least one of, but not limited to, a dielectric layer containing at least one of magnesium oxide (MgO), zirconium oxide (ZrO₂), aluminum nitride (AlN), lead zirconate titanate (PZT), gallium arsenic (GaAs), hafnium oxide (HfO₂), aluminum oxide (Al₂O₃), titanium oxide (TiO₂), and zinc oxide (ZnO), and a metal layer containing at least one of aluminum (Al), nickel (Ni), chromium (Cr), platinum (Pt), gallium (Ga), and hafnium (Hf), but may be formed of a material different from a material of the sacrificial layer 140a.

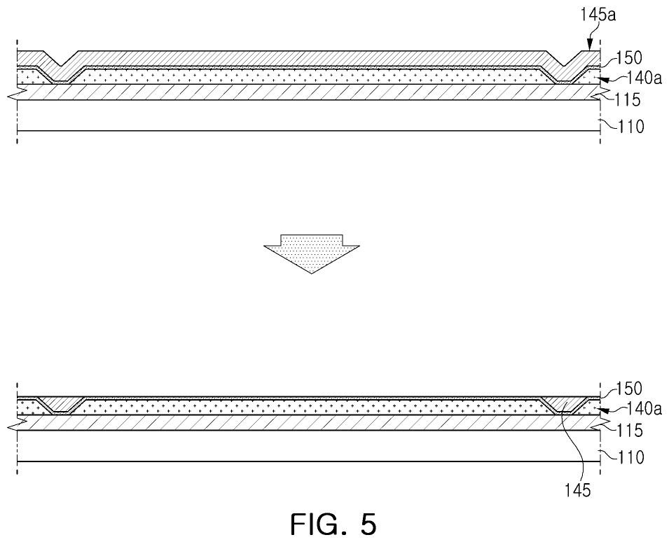

Subsequently, as illustrated in FIG. 5, an etch-stop layer 145a may be formed on the membrane layer 150. In this example, the etch-stop layer 145a may be also filled in the pattern P.

The etch-stop layer 145a may be formed to have a thickness that completely fills the pattern P. Accordingly, the etch-stop layer 145a may be formed to be thicker than the sacrificial layer 140a.

The etch-stop layer 145a may be formed of a material that is the same as a material of the insulating layer 115. However, the one or more examples are not limited thereto.

Subsequently, the etch-stop layer 145a may be removed to expose the membrane layer 150 externally.

In this example, a portion of the etch stop layer that is filled in the pattern P may remain, and the remaining etch-stop layer 145a may operate as the etch-stop portion 145.

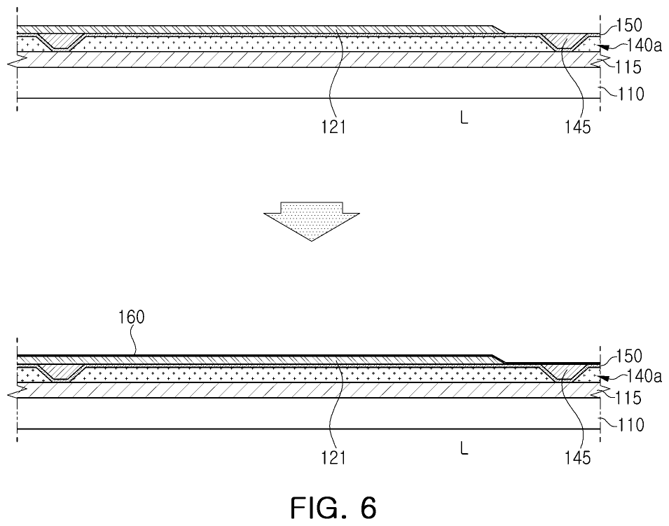

Subsequently, as illustrated in FIG. 6, the first electrode 121 may be formed on an upper surface of the membrane layer 150.

In the present example embodiment, the first electrode 121 may be formed of a conductor, for example, may be formed of a metal including, but not limited to, gold, molybdenum, ruthenium, iridium, aluminum, platinum, titanium, tungsten, palladium, tantalum, chromium, nickel, or at least one of gold, molybdenum, ruthenium, iridium, aluminum, platinum, titanium, tungsten, palladium, tantalum, chromium, and nickel. However, the one or more examples are not limited thereto.

The first electrode 121 may be formed by forming a conductor layer to cover the entire membrane layer 150, and then removing any unnecessary portions.

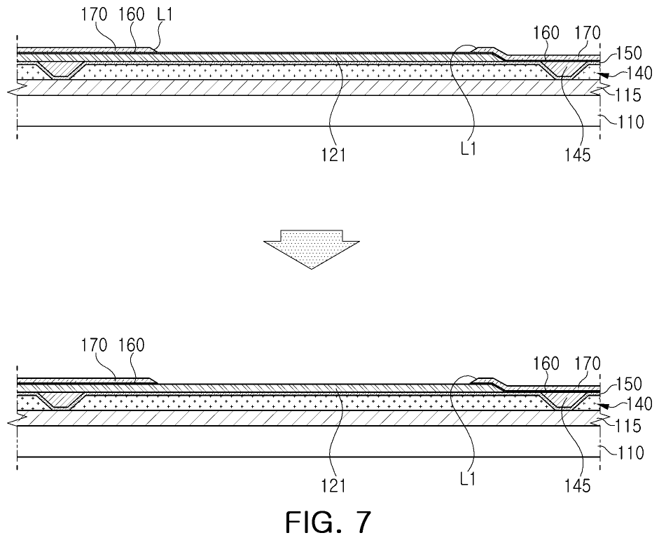

Subsequently, referring to FIG. 7, the loss prevention film 160 may be formed on the upper surface of the first electrode 121.

The loss prevention film 160 may be formed to prevent the first electrode 121 from being damaged in the process of patterning the insertion layer 170. Accordingly, the loss prevention film 160 may be formed on the entire surface of the first electrode 121, and may extend to an upper portion of the membrane layer 150, as necessary.

As described above, the loss prevention film 160 may be formed of a dielectric such as, but not limited to, aluminum nitride (AlN), silicon oxide (SiO₂), aluminum oxide (Al₂O₃), silicon nitride (Si₃N₄), magnesium oxide (MgO), zirconium oxide (ZrO₂), lead zirconate titanate (PZT), gallium arsenide (GaAs), hafnium oxide (HfO₂), titanium oxide (TiO₂), or zinc oxide (ZnO), and may be formed of a material different from a material of the insertion layer 170.

In the present example embodiment, the loss prevention film 160 may be formed to prevent the first electrode 121 from being lost or damaged during the patterning of the insertion layer 170. Accordingly, it may be advantageous that the insertion layer 170 is formed of a material that is not etched or removed in a dry etching process, and is formed to be as thin as possible if the insertion layer 170 protects the first electrode 121 in the dry etching process.

As described above, in the present example embodiment, the loss prevention film 160 may be formed to have a thickness of 10 Å to 500 Å, and may be formed to have a thickness of 100 Å to 300 Å so as to enhance manufacturing reliability.

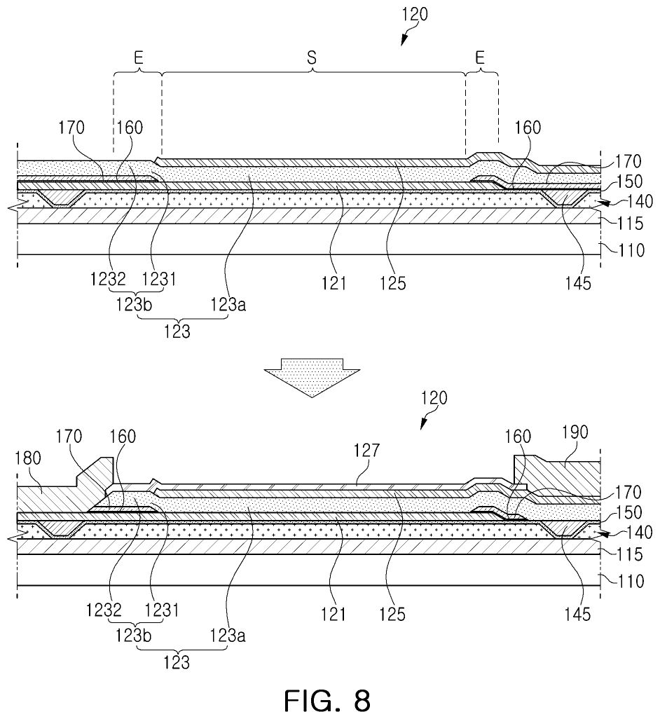

Subsequently, as illustrated in FIG. 7, the insertion layer 170 may be formed on the loss prevention film 160. The insertion layer 170 may be completed by forming the insertion layer 170 to have a wide area along a surface of the loss prevention film 160, and then removing a portion of the loss prevention film 160 that is disposed in a region corresponding to a central portion (S in FIG. 8).

Accordingly, when the insertion layer 170 is completed, a portion of the loss prevention film 160 that is disposed in the central portion S may be exposed externally of the insertion layer 170. Additionally, the insertion layer 170 is formed to cover a portion of the first electrode 121 along a circumference of the first electrode 121. For example, as illustrated in FIG. 8, an edge portion of the first electrode 121 disposed in the extension portion E may be disposed on a lower portion of the insertion layer 170.

As the insertion layer 170 is patterned by a dry etching method, a side surface of the insertion layer 170 disposed to be adjacent to the central portion S may be formed as the first inclined surface L1. As described above, an inclination angle (θ1 in FIG. 3) of the first inclined surface L1 of the insertion layer 170 may be formed to be within a range of 5° to 70°. The first inclined surface L1 may be an important element in forming a reflection structure reflecting a lateral wave into the resonant portion 120. However, when the insertion layer 170 is patterned through a wet etching process, it may be difficult to accurately form the inclined surface L1 of the insertion layer 170 at a specific angle. Accordingly, in the present example embodiment, the insertion layer 170 may be patterned by the dry etching method.

The insertion layer 170 may be formed of, for example, a dielectric such as, but not limited to, silicon oxide (SiO₂), aluminum nitride (AlN), aluminum oxide (Al₂O₃), silicon nitride (SiN), magnesium oxide (MgO), zirconium oxide (ZrO₂), lead zirconate titanate (PZT), gallium arsenide (GaAs), hafnium oxide (HfO₂), aluminum oxide (Al₂O₃), titanium oxide (TiO₂), or zinc oxide (ZnO), but may be formed of a material different from that of the piezoelectric layer 123.

The loss prevention film 160 may need to protect the first electrode 121 such that the first electrode 121 is not lost or damaged in the present process. Accordingly, the loss prevention film 160 may be formed of a material that is not removed in a dry etching process of patterning the insertion layer 170.

Subsequently, the loss prevention film 160 may be removed to expose the first electrode 121. A process of removing the loss prevention film 160 may be performed by a wet etching method, as an example.

In the present process, a portion of the loss prevention film 160 exposed externally of the insertion layer 170 may be completely removed. However, the present disclosure is not limited thereto, and it is also possible to remove only the portion disposed in the central portion S, as necessary.

In the wet etching method, etching may be performed more rapidly than etching performed by the dry etching method. Accordingly, a second inclination angle (02 in FIG. 3) of the loss prevention film 160 formed by an etching process may be equal to or greater than the first inclination angle θ1 of the insertion layer 170.

In a process of etching the loss prevention film 160, the insertion layer 170 may operate as an etching mask. Accordingly, the second inclined surface L2 of the loss prevention film 160 toward the central portion S may extend from the first inclined surface L1 of the insertion layer 170. For example, an upper end of the second inclined surface L2 may be formed to be in contact with a lower end of the first inclined surface L1.

Additionally, in the present process, an etching solution, that reacts only to a material of the loss prevention film 160, may be used. Accordingly, even when the etching process is performed, the insertion layer 170 or the first electrode 121 may not be damaged.

Subsequently, as illustrated in FIG. 8, the piezoelectric layer 123 may be formed on the first electrode 121 and the insertion layer 170.

In the present example embodiment, the piezoelectric layer 123 may be formed of aluminum nitride (AlN). However, the one or more examples are not limited thereto, and zinc oxide (ZnO), doped aluminum nitride, lead zirconate titanate, quartz, or the like may be selectively used as a material of the piezoelectric layer 123. Additionally, doped aluminum nitride may further include a rare earth metal or a transition metal. For example, the rare earth metal may include at least one of, but not limited to, scandium (Sc), erbium (Er), yttrium (Y), and lanthanum (La). The transition metal may include at least one of hafnium (Hf), titanium (Ti), zirconium (Zr), tantalum (Ta), niobium (Nb), and magnesium (Mg).

For example, the piezoelectric layer 123 may be formed of a material different from a material of the insertion layer 170.

The piezoelectric layer 123 may be formed by forming a piezoelectric material on the entire surface formed by the first electrode 121 and the insertion layer 170, and then partially removing ay unnecessary portions. In the present example embodiment, after forming the second electrode 125, unnecessary parts of the piezoelectric material are removed to complete the piezoelectric layer 123. However, the one or more examples are not limited thereto, and it is also possible to complete the piezoelectric layer 123 before forming the second electrode 125.

The piezoelectric layer 123 may be formed to cover a portion of the first electrode 121 and the insertion layer 170, and thus the piezoelectric layer 123 may be formed according to a shape of a surface formed by the first electrode 121 and the insertion layer 170.

As described above, only a portion corresponding to the central portion S of the first electrode 121 may be exposed externally of the insertion layer 170. Accordingly, the piezoelectric layer 123 that is formed on the first electrode 121 may be positioned within the central portion S. Additionally, the bent portion 123b of the piezoelectric layer 123 that is formed on the insertion layer 170, may be positioned within the extension portion E.

Subsequently, as illustrated in FIG. 8, a second electrode 125 may be formed on an upper portion of the piezoelectric layer 123. In the present example embodiment, the second electrode 125 may be formed of a conductor. In an example, the second electrode 125 may be formed of a metal including, but not limited to, gold, molybdenum, ruthenium, iridium, aluminum, platinum, titanium, tungsten, palladium, tantalum, chromium, nickel, or at least one of gold, molybdenum, ruthenium, iridium, aluminum, platinum, titanium, tungsten, palladium, tantalum, chromium, and nickel. However, the one or more examples are not limited thereto.

The second electrode 125 may be basically formed on the piezoelectric portion 123a of the piezoelectric layer 123. As described above, the piezoelectric portion 123a of the piezoelectric layer 123 may be positioned within the central portion S. Accordingly, the second electrode 125 disposed on the piezoelectric layer 123 may also be disposed within the central portion S.

Additionally, in the present example embodiment, the second electrode 125 may also be formed on the inclined portion 1231 of the piezoelectric layer 123. Accordingly, as described above, the second electrode 125 may be partially disposed within the entire central portion S and the extension portion E.

Subsequently, the protective film 127 may be formed along a surface formed by the second electrode 125 and the piezoelectric layer 123. Although not illustrated, the protective film 127 may also be formed on the insertion layer 170 that is exposed externally.

The protective film 127 may be formed of one of a silicon oxide-based insulating material, silicon nitride-based insulating material, and aluminum nitride-based insulating material. However, the one or more examples are not limited thereto.

Subsequently, the protective film 127 and the piezoelectric layer 123 may be partially removed to partially expose the first electrode 121 and the second electrode 125, and the first metal layer 180 and the second metal layer 190 may be formed on the exposed portions, respectively.

The first metal layer 180 and the second metal layer 190 may be formed of a material such as, but not limited to, gold (Au), a gold-tin (Au—Sn) alloy, copper (Cu), or a copper-tin (Cu—Sn) alloy, and may be formed by depositing the material on the first electrode 121 or the second electrode 125. However, the one or more examples are not limited thereto.

Subsequently, the BAW resonator 100 illustrated in FIG. 2 may be completed by forming the cavity C.

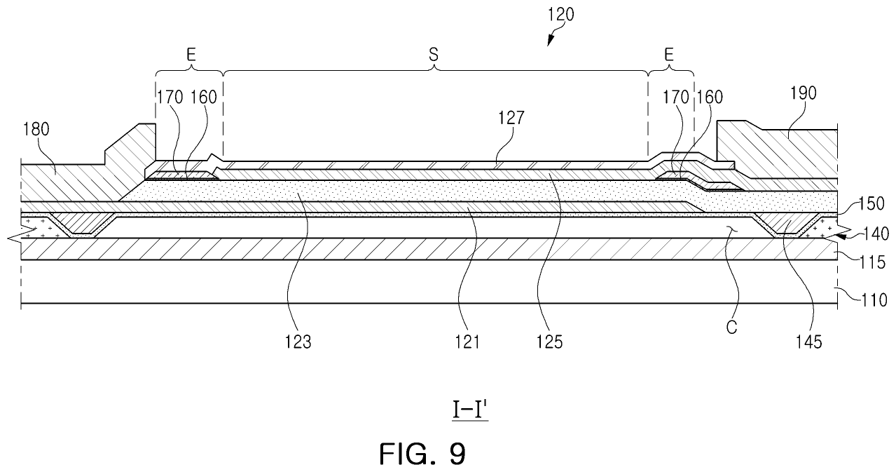

Referring to FIG. 9. the cavity C may be formed by removing a portion of the sacrificial layer that is positioned within the etch-stop portion 145 from the sacrificial layer 140a, and a remaining portion of the sacrificial layer 140a may form the above-described support layer 140.

In an example, the sacrificial layer 140a may be removed by an etching method. When the sacrificial layer 140a is formed of a material such as polysilicon or a polymer, the sacrificial layer 140a may be removed by a dry etching method using a halide-based etching gas (for example, XeF₂) such as fluorine (F) or chlorine (CI).

In the BAW resonator according to the present example embodiment configured as described above, the extension portion E of the resonant portion 120 may be formed to be thicker than the central portion S by the insertion layer 170, such that vibrations generated in the central portion S may be suppressed from escaping externally, thereby increasing a Q-factor of the acoustic wave resonator.

Additionally, the BAW resonator according to the present embodiment may include the loss prevention film 160 to prevent partial loss of the first electrode 121 in the process of patterning the insertion layer 170. When there is no loss prevention film unlike the present example embodiment, a dry etching process of patterning the insertion layer 170 may be performed in a state in which the first electrode 121 is exposed, such that the first electrode 121 may also be partially lost in the etching process.

Accordingly, it may be confirmed that a thickness of the first electrode 121 disposed in the central portion S is smaller than a thickness of the first electrode 121 disposed below the insertion layer 170. Additionally, as surface roughness of the first electrode 121 increases for the above-described reason, the crystallinity of the piezoelectric layer 123 deposited on an upper surface of the first electrode 121 may be lowered, resulting in an increase in frequency dispersion and noise of the BAW resonator, and degradation in filter performance.

Conversely, when the loss prevention film 160 is formed as in the present embodiment, the first electrode 121 may be prevented from being lost or damaged, such that it may be confirmed that the thickness of the first electrode 121 disposed in the central portion S is the same as the thickness of the first electrode 121 disposed below the insertion layer 170, thereby minimizing frequency dispersion or noise, and improving filter performance.

As illustrated in FIG. 7, in an example, the loss prevention film 160 may also be formed on the first electrode 121, and then the piezoelectric layer 123 may be stacked on the loss prevention film 160 without removing the loss prevention film 160 of the central portion S. However, in this example, a surface of the loss prevention film 160 may be damaged in the process of patterning the insertion layer 170 by the dry etching method, such that it may be confirmed that the crystallinity of the piezoelectric layer 123 deposited on the loss prevention film 160 may be lowered, resulting in great degradation in filter performance. It may be confirmed that the filter performance is improved in a structure in which the piezoelectric layer 123 is stacked after the damaged loss prevention film 160 is removed as in the present embodiment.

Additionally, even when the loss prevention film 160 is added, the filter performance may be degraded even when the thickness of the loss prevention film 160 is excessively thick. As described above, when the thickness of the loss prevention film 160 exceeds 500 Å, it may be confirmed that the filter performance is greatly degraded. However, the loss prevention film 160 according to the present example embodiment may be formed to have a thickness of 10 Å to 500 Å, such that the filter performance may be improved by minimizing frequency dispersion or noise without a degradation in performance.

The one or more examples are not limited to the above-described example embodiments, and various modifications may be made.

FIG. 9 is a cross-sectional view of an example BAW resonator, in accordance with one or more embodiments.

Referring to FIG. 9, in the example BAW resonator according to the present example embodiment, the insertion layer 170 may be positioned on an upper portion of the piezoelectric layer 123. Accordingly, the piezoelectric layer 123 may be formed to be entirely flat without a bent portion (such as the bent portion 123b in FIG. 2) according to the above-described example embodiment, and the loss prevention film 160 disposed on the upper portion of the piezoelectric layer 123 may be positioned between the piezoelectric layer 123 and the insertion layer 170.

As the insertion layer 170 is formed on the piezoelectric layer 123, the loss prevention film 160 according to the present example embodiment may be formed to prevent partial loss of the piezoelectric layer 123 in the process of forming the insertion layer 170 on the piezoelectric layer 123.

Accordingly, the loss prevention film 160 may be formed of an AlN-based material, a material of the piezoelectric layer 123, and a material having high etch selectivity. For example, the loss prevention film 160 according to the present example embodiment may be formed of a metal material such as titanium (Ti), chromium (Cr), or copper (Cu).

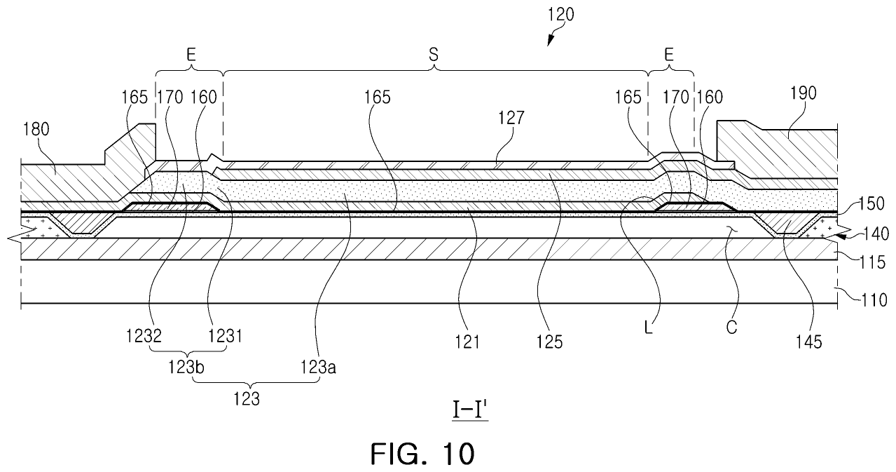

Referring to FIG. 10, the BAW resonator of the present example embodiment may include a seed layer 165 that is formed of aluminum nitride (AlN) for deposition of the first electrode 121 on the membrane layer 150. Specifically, the seed layer 165 may be disposed between the membrane layer 150 and the first electrode 121. The seed layer 165 may be formed of a dielectric or metal having an HCP structure in addition to AlN. In the example of metal, for example, the seed layer 165 may be formed of titanium (Ti).

FIG. 10 is a cross-sectional view of an example BAW resonator, in accordance with one or more examples.

Referring to FIG. 10, in the example BAW resonator, the first electrode 121 may be positioned on an upper portion of the insertion layer 170. Specifically, the first electrode 121 may be disposed along a surface formed by the insertion layer 170, the loss prevention film 160, and the membrane layer 150.

Additionally, the volumetric acoustic resonator of the present example embodiment may include a seed layer 165 for deposition of the first electrode 121. In the seed layer 165, the entirety of the first electrode 121 may be disposed on the seed layer 165. Accordingly, the seed layer may be disposed along a surface formed by the insertion layer 170, the loss prevention film 160, and the membrane layer.

In an example, the seed layer 166 may be formed of aluminum nitride (AlN), but may also be formed using a dielectric or metal having an HCP structure. For example, the seed layer may be formed of titanium (Ti).

Since the insertion layer 170 may be formed on the membrane layer 150, the loss prevention film 160 according to the present embodiment may be formed to prevent partial loss of the membrane layer 150 in the process of forming the insertion layer 170 on the membrane layer 150.

Accordingly, the loss prevention film 160 may be formed of a material having high etch selectivity with respect to the membrane layer 150. For example, when the membrane layer 150 is a metal material, the loss prevention film 160 may be formed of a dielectric layer, and when the membrane layer 150 is a dielectric layer, the loss prevention layer 160 may be formed of a metal material.

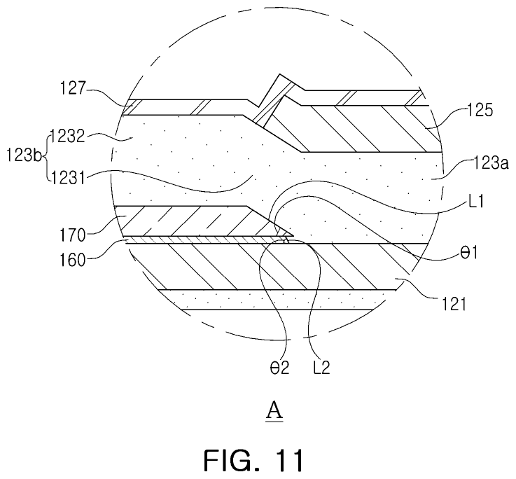

FIG. 11, a partial cross-sectional view of an example BAW resonator in accordance with an embodiment, illustrates a cross-section corresponding to that of FIG. 3.

Referring to FIG. 11, in the example BAW resonator according to the present example embodiment, a step difference may be formed between the first inclined surface L1 and the second inclined surface L2. As described above, the patterning of the insertion layer 170 may be performed by a dry etching method, and the patterning of the loss prevention film 160 may be performed by a wet etching method, such that the step difference may be formed by adjusting an etching environment, speed, or the like. The step difference may be configured such that an upper end of the second inclined surface L2 is in contact with a lower surface of the insertion layer 170, rather than a lower end of the first inclined surface L1. Accordingly, the upper end of the second inclined surface L2 may be spaced apart from the lower end of the first inclined surface L1 by a predetermined distance to be in contact with the lower surface of the insertion layer 170.

While this disclosure includes specific examples, it will be apparent to one of ordinary skill in the art, after an understanding of the disclosure of this application, that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, the scope of the disclosure is defined not by the detailed description, but by the claims and their equivalents, and all variations within the scope of the claims and their equivalents are to be construed as being included in the disclosure.

What is claimed is:

1. A bulk-acoustic wave (BAW) resonator, comprising:
a central portion in which a first electrode, a piezoelectric layer, and a second electrode are sequentially stacked on a substrate; and
an extension portion that extends externally from the central portion, and an insertion layer and a loss prevention film are disposed in the extension portion between the substrate and the second electrode,
wherein the loss prevention film is formed to have a thickness of 50 Å to 500 Å,
wherein the insertion layer is stacked on the loss prevention film, and has a side surface that opposes the central portion, and the side surface is formed as a first inclined surface having a first inclination angle,
wherein the loss prevention film has a side surface that opposes the central portion, and the side surface of the loss prevention film is formed as a second inclined surface having a second inclination angle, and
wherein the second inclination angle is greater than the first inclination angle.

2. The BAW resonator of claim 1, wherein the second inclined surface extends from the first inclined surface.

3. The BAW resonator of claim 1, wherein the insertion layer and the loss prevention film are disposed between the first electrode and the piezoelectric layer in the extension portion.

4. The BAW resonator of claim 3, wherein the loss prevention film comprises aluminum nitride (AlN).

5. The BAW resonator of claim 1, wherein the insertion layer and the loss prevention film are disposed between the piezoelectric layer and the second electrode in the extension portion.

6. The BAW resonator of claim 5, wherein the loss prevention film is formed of a metal material.

7. The BAW resonator of claim 1, wherein the insertion layer and the loss prevention film are disposed between the substrate and the first electrode in the extension portion.

8. The BAW resonator of claim 7, further comprising:
a seed layer disposed on a lower portion of the first electrode,
wherein at least a portion of the seed layer is disposed between the insertion layer and the first electrode.

9. The BAW resonator of claim 2, wherein the second inclination angle of the loss prevention film is equal to or greater than 50°.

10. The BAW resonator of claim 2, wherein the loss prevention film is formed of a material that is the same as a material of the piezoelectric layer.

11. The BAW resonator of claim 1, wherein an upper end of the second inclined surface is spaced apart from a lower end of the first inclined surface by a predetermined distance to be in contact with a lower surface of the insertion layer.

12. A method of manufacturing a bulk-acoustic wave (BAW) resonator including a central portion in which a plurality of thin film layers are stacked and an extension portion that extends externally from the central portion and having an insertion layer additionally disposed thereon, the method comprising:
forming a first thin film layer;
forming a loss prevention film on the first thin film layer;
forming the insertion layer on an entire area of the loss prevention film;
removing the insertion layer disposed in the central portion after forming the insertion layer on the entire area of the loss prevention film;
exposing the first thin film layer by removing the loss prevention film that is exposed externally of the insertion layer; and
forming a second thin film layer on the exposed first thin film layer,
wherein the loss prevention film is formed to have a thickness of 50 Å to 500 Å,
wherein the removing of the insertion layer comprises forming a side surface of the insertion layer that opposes the central portion as a first inclined surface,
wherein the removing of the loss prevention film comprises forming a side surface of the loss prevention film that opposes the central portion as a second inclined surface, and
wherein the second inclined surface extends from the first inclined surface.

13. The method of claim 12, wherein:
the removing of the insertion layer is performed by a dry etching method, and
the removing of the loss prevention film is performed by a wet etching method.

14. The method of claim 13, wherein, in the forming of the loss prevention film, the second inclined surface has an inclination angle equal to or greater than 50°.

15. The method of claim 12, wherein:
the first thin film layer is a lower electrode, and
the second thin film layer is a piezoelectric layer.

16. The method of claim 12, wherein:
the first thin film layer is a piezoelectric layer, and
the second thin film layer is an upper electrode.
